(19) United States
(12) Patent Application Publication
(10) Pub. No.: US 2026/0059689 A1
(43) Pub. Date: Feb. 26, 2026

(54) SPRING-BIASED MOVABLE CONNECTOR ASSEMBLY FOR STORAGE-DEVICE BAYS

(71) Applicant: Aivres Systems Inc., Fremont, CA (US)

(72) Inventor: Xiang Yin HONG, Taipei City (TW)

(21) Appl. No.: 19/378,404

(22) Filed: Nov. 4, 2025

(51) Int. Cl. H05K 7/14; H05K 7/18

(52) U.S. Cl. CPC H05K 7/1489; H05K 7/1417; H05K 7/1441; H05K 7/1452; H05K 7/1492; H05K 7/18

(57) ABSTRACT

A storage-device bay includes a fixed-side bracket and a movable connector subassembly that translates along an insertion axis. The subassembly carries a connector PCBA with a mating connector and is biased toward the fixed-side bracket by at least one resilient member, preferably springs captured under abutments such as screw heads on the bracket. During insertion, the device-side connector mates while the subassembly translates against the bias; in a seated state, the bias maintains axial compressive preload across the mated connectors to absorb tolerances and improve contact reliability. Variants include a travel stop, alignment features, a PCBA support plate, multi-connector PCBA for multi-bay use with group translation, and independently movable sections providing localized preload per bay.

### TECHNICAL FIELD

This disclosure relates to electromechanical interconnects for information-handling equipment. More particularly, it describes a storage-device bay assembly with a movable, spring-biased connector subassembly to maintain axial compressive preload for reliable electrical contact, including single-and multi-bay configurations.

### BACKGROUND

Conventional hard disk drives (HDDs) or solid-state drives (SSDs) bays typically anchor the backplane connector to the chassis and count on a fixed “reserve” clearance between the drive, its carrier/bracket, and the connector to soak up dimensional variation. That variation is unavoidable in production: sheet-metal spring-back and coating thickness shift bracket geometry; PCB thickness, connector standoff height, and solder-float change backplane datums; plastics shrink differently lot-to-lot; fastener torque, bushing wear, and tolerance on rails, guides, and cages add stack-up; even temperature and humidity move parts over time. Because different suppliers and SKUs contribute to the same stack, the effective gap seen at the connector can swing widely across builds and across the product's life.

A fixed clearance reserve is therefore a compromise that is rarely “perfect.” If the reserve is set large to avoid tight fits, insertion becomes easy but the mated interface can sit with residual clearance, reducing contact normal force and making continuity susceptible to vibration, shock, and thermal cycling. If the reserve is set small to raise contact force, insertion forces climb, misalignment damage becomes more likely, and connectors wear prematurely, especially in service environments with frequent swaps. Fixed reserves also fail to track drift in the field: paint rub-off, latch wear, and repeated thermal cycles change the geometry, but the clearance cannot adjust with it.

Practically, these effects show up as intermittent links, CRC errors, and “no drive found” returns that consume service time and erode reliability metrics. They force over-tight manufacturing controls, and complicate multi-vendor bays where drives and carriers vary. What is needed is a bay architecture that automatically absorbs dimensional variation during insertion and then enforces a defined axial compressive preload at the connector interface in service, so contact force and signal integrity are maintained without delicate tuning of fixed clearances.

### SUMMARY

The technical solution described in this disclosure is a “tight-press” mechanical design that introduces a spring-biased, movable connector side opposite a fixed bracket side, so the connector PCBA (printed circuit board assembly) and its support plate translate under spring force to take up whatever tolerance remains and maintain compressive engagement. In some embodiments, the disclosure provides two form factors (multi-action set and single-action set) and specifies the principal elements: a fixed-side bracket, a movable connector PCBA with its bracket, one or more springs, screws limiting spring degrees of freedom, and screws fixing the movable connector PCBA to its bracket. During module insertion, the fixed-side stays put while the movable connector PCBA shifts rearward, the spring force eliminates the gap, and a sustained spring preload keeps contact pressure and signal integrity without adding parts or assembly steps. The technical benefits include resolving contact failures caused by tolerance stack-ups and simplifying installation with fewer components.

In one general aspect, an assembly is provided for coupling a storage device to a host. The assembly includes a fixed-side bracket configured to receive the storage device and a movable connector subassembly mounted to the fixed-side bracket for linear translation along an insertion axis. The movable connector subassembly comprises a connector printed circuit board assembly (PCBA) carrying a mating connector and at least one resilient member arranged to bias the movable connector subassembly toward the fixed-side bracket. During insertion of the storage device along the insertion axis, a device-side connector of the storage device mates with the mating connector while insertion force translates the movable connector subassembly against the at least one resilient member, and, in a seated state, the at least one resilient member maintains an axial compressive preload across the device-side connector and the mating connector.

In some embodiments, the at least one resilient member is disposed on an exterior surface of the movable connector subassembly that faces away from the fixed-side bracket and is captured between the exterior surface and an abutment fixed to the fixed-side bracket to bias the movable connector subassembly toward the fixed-side bracket. The abutment can comprise a screw secured to the fixed-side bracket, the screw having a head that restrains the resilient member. The axial compressive preload can be configured to accommodate accumulated dimensional tolerances, reduce residual clearance, and increase engagement force between the storage device and the connector PCBA. The fixed-side bracket can be configured to support the storage device during insertion along the insertion axis and to secure the storage device in a seated state by a locking mechanism located at a first end opposite a second end at which the movable connector subassembly is mounted. The fixed-side bracket can further comprise an alignment feature configured to guide the storage device into coaxial alignment with the mating connector prior to mating. A travel stop can limit translation of the movable connector subassembly away from a home position to a defined stroke.

In further embodiments, the abutment can comprise a head of a screw secured to the fixed-side bracket and extending through the movable connector subassembly, and the at least one resilient member can comprise a coil spring seated between the exterior surface and the head of the screw, with the head of the screw acting as a spring seat or limiter of free length. The movable connector subassembly can further comprise a PCBA plate that supports the connector PCBA, wherein the connector PCBA is sandwiched between the PCBA plate and the fixed-side bracket. The PCBA plate can be formed of metal or plastic and the fixed-side bracket can be formed of metal or plastic. The storage device can comprise a hard disk drive or a solid-state drive, and the mating connector can comprise a SATA, SAS, PCIe, or edge-card interface.

In multi-bay embodiments, the connector PCBA carries a plurality of mating connectors respectively positioned to align with a corresponding plurality of slots of the fixed-side bracket that are configured to receive a plurality of storage devices. In some of these embodiments, the at least one resilient member biases the movable connector subassembly such that the plurality of mating connectors translate together along the insertion axis. In other embodiments, the movable connector subassembly comprises a plurality of separately movable sections respectively corresponding to the plurality of mating connectors, each of the plurality of movable sections carrying a respective mating connector and having a corresponding resilient member that biases that movable section toward the fixed-side bracket, wherein the plurality of movable sections translate substantially independently along the insertion axis to provide localized axial compressive preload for the plurality of storage devices.

In another general aspect, a method of manufacturing the assembly includes providing a fixed-side bracket configured to receive the storage device; assembling a movable connector subassembly comprising a connector printed circuit board assembly (PCBA) carrying a mating connector and at least one resilient member arranged to bias the movable connector subassembly toward the fixed-side bracket; and mounting the movable connector subassembly to the fixed-side bracket by guide features that constrain linear translation along an insertion axis. During insertion of the storage device along the insertion axis, a device-side connector of the storage device mates with the mating connector while insertion force translates the movable connector subassembly against the at least one resilient member, and, in a seated state, the at least one resilient member maintains an axial compressive preload across the device-side connector and the mating connector.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 illustrates a schematic view of a storage-device bay assembly configured to receive a storage device and to couple a device-side connector of the storage device with a mating connector carried on a non-movable printed circuit board assembly (PCBA), in accordance with some embodiments.

FIG. 2 illustrates two perspective views of a storage-device bay assembly with a movable connector subassembly, in accordance with some embodiments.

FIG. 3 illustrates a side view of the storage-device bay assembly with a movable connector subassembly, in accordance with some embodiments.

FIG. 4 illustrates a comparison between pre-insertion and during/after-insertion of a storage device using the storage-device bay assembly with a movable connector subassembly, in accordance with some embodiments.

FIG. 5 illustrates a multi-bay assembly with a shared movable connector subassembly, in accordance with some embodiments.

FIG. 6 illustrates a single-bay assembly with a shared movable connector subassembly, in accordance with some embodiments.

FIG. 7 illustrates an exploded view of a movable connector subassembly, in accordance with some embodiments.

FIG. 8 illustrates an example method for manufacturing a storage device bay assembly with a movable connector subassembly, in accordance with some embodiments.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

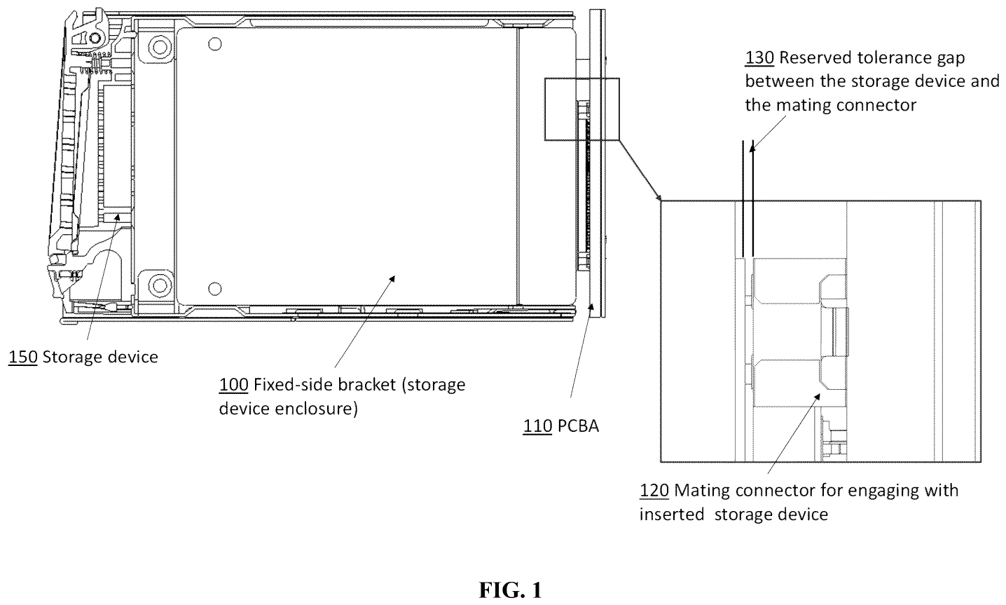

FIG. 1 illustrates a schematic view of a storage-device bay assembly configured to receive a storage device and to couple a device-side connector of the storage device with a mating connector carried on a non-movable connector printed circuit board assembly (PCBA), providing a baseline fixed-connector configuration for comparison with the movable-connector embodiments described below.

As shown, one or more storage devices 150, such as hard disk drives (HDDs) or solid-state drives (SSDs), are received in a fixed-side bracket 100 (also referred to as a bracket, a storage bay, or a storage-device enclosure). In typical server or system deployments, multiple storage devices 150 are grouped in the storage bay 100 to form an array, enabling collective operation with other components of the system.

During installation, the storage device 150 is inserted into and locked within the fixed-side bracket 100 so that its device-side connector engages with the mating connector 120. The mating connector 120 is required to provide both mechanical retention and electrical coupling between the storage device 150 and the host system, ensuring that power and data signals can be reliably exchanged.

In this baseline configuration, the connector PCBA is non-movable, and a reserved tolerance gap 130 is provided between the storage device 150 and the fixed-side bracket 100. This gap is intended to accommodate dimensional variation and assumes that all storage devices 150 conform to the same nominal size. However, in practice, storage devices from different manufacturers or even different production lots may vary in dimensions due to machining tolerances, surface coatings, fastener tolerances, and other cumulative stack-ups.

When the reserved tolerance gap 130 is too large, the device-side connector may not seat fully, resulting in weak contact pressure, intermittent signal continuity, or susceptibility to vibration-induced disconnection. Conversely, when the gap is too small, insertion force increases, risking damage to the mating connector 120, premature wear, or even misalignment that prevents proper seating. These practical issues make the fixed-gap design unreliable in high-density or high-service environments, motivating the movable connector embodiments described in subsequent figures.

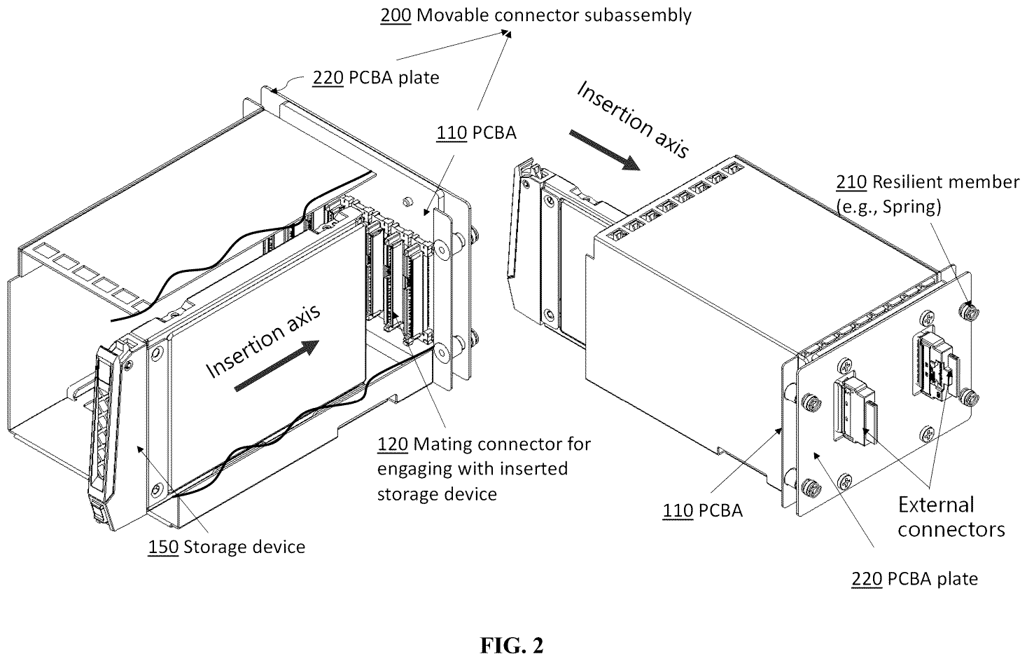

FIG. 2 illustrates two perspective views of a storage-device bay assembly in which a movable connector subassembly (also referred to as a subassembly) 200 is mounted to a fixed-side bracket 100 for linear translation along a defined insertion axis. In the illustrated embodiment, the movable connector subassembly 200 includes a PCBA 110 on which one or more mating connectors 120 are mounted to electrically couple to a device-side connector of a storage device 150 when the storage device is advanced along the insertion axis (arrow in FIG. 2). Thus the PCBA 110 is also called connector PCBA 110.

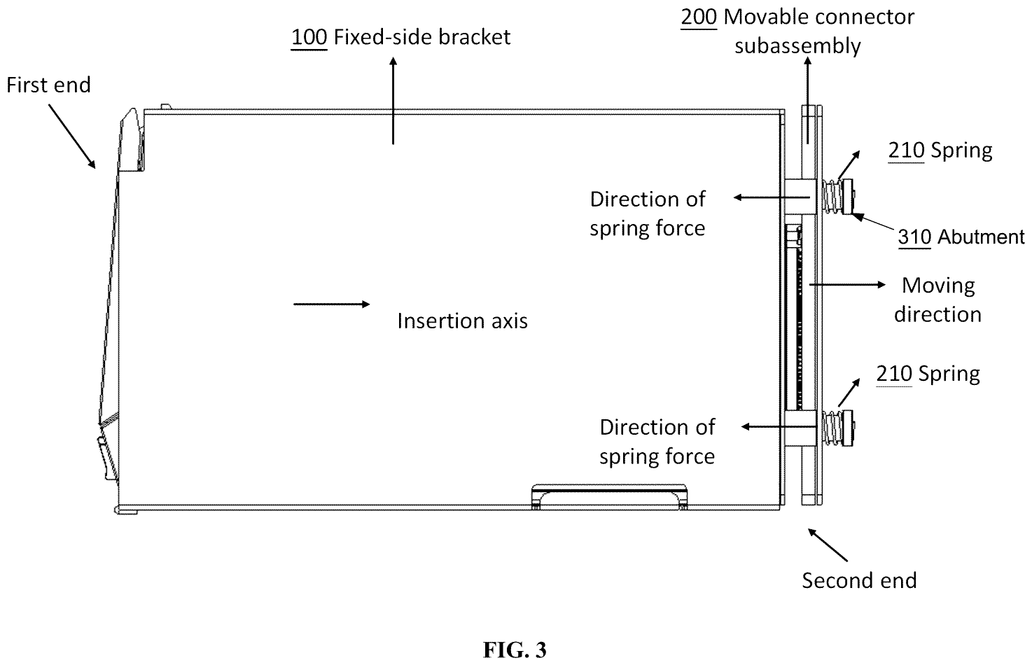

In the embodiment illustrated in FIG. 2, a set of resilient members 210 is disposed on an exterior surface of the movable connector subassembly 200 that faces away from the fixed-side bracket 100; each resilient member 210 is captured beneath an abutment (e.g., 310 in FIG. 3) fixed to the bracket (e.g., the head of a screw), so that the abutment reacts the spring force of the resilient member 210 and biases the subassembly 200 toward the bracket 100 to a home position (e.g., springs in its relaxed state) while permitting controlled translation against the bias during insertion.

FIG. 2 also show external connectors at the rear of the storage bay that couple the connector PCBA 110 to other subsystems of the server, for example power distribution harnesses and host I/O such as SATA, SAS, or PCIe.

In some embodiments, the movable connector subassembly 200 includes the connector PCBA 110 carrying the mating connector(s) 120 and a PCBA plate 220 that supports the connector PCBA 110. The connector PCBA 110 is positioned adjacent the fixed-side bracket 100 so that the mating connector(s) 120 project toward the storage device 150. In some embodiments, the connector PCBA 110 and a PCBA plate 220 are fastened together so they translate as a unit relative to the bracket 100. In the illustrated arrangement the connector PCBA 110 is effectively sandwiched between the fixed-side bracket 100 and the PCBA plate 220, with the plate 220 providing a stiff backing surface, spring seats, and interfaces for guide hardware.

In some embodiments, the resilient members 210 reside on the exterior face of the PCBA plate 220 that faces away from the fixed-side bracket 100. In one example, the resilient members 210 are springs. As shown, each spring is captured under an abutment fixed to the bracket e.g., the head of a screw whose shank threads into the fixed-side bracket 100. The screw head overlies the spring to react the spring force, act as a spring seat, and limit free length so the spring cannot escape laterally. When the storage device 150 is advanced along the insertion axis and its device-side connector meets the mating connector 120, continued insertion force translates the entire movable connector subassembly 200 rearward against the resilient members 210. Once the storage device reaches its seated position and is latched, the springs remain partially compressed and apply a non-zero axial compressive preload across the mated connectors.

Locating the resilient members 210 on the outward-facing side of the PCBA plate 220 permits easy assembly and service access; in some embodiments the entire movable connector subassembly 200 functions as a field-replaceable cartridge that can be removed by loosening the abutment screws, swapped, and reinstalled without disturbing the fixed-side bracket 100.

In some embodiments, linear motion of the movable connector subassembly 200 is constrained by cooperating guide features between the PCBA plate 220 and the bracket 100, such as rail-and-channel profiles. A travel stop can be provided by the end of a slot or a positive hard stop on the fixed-side bracket 100 to define a maximum rearward stroke. In some examples, a spacer, shim, or torque window on the abutment screws sets the home-position displacement and the preload that will be present in the seated state.

Materials for the PCBA plate 220 may be metal, such as steel or aluminum, to provide stiffness and a ground path, or molded plastic with conductive inserts or coatings to achieve electrostatic discharge control. This combination of flexibility and resilience accommodate accumulated dimensional tolerances, reduces residual clearance, and raises contact normal force so continuity is preserved under vibration and thermal cycling.

In a different implementation (not shown on FIG. 2), the resilient members 210 are arranged inboard, i.e., between the connector PCBA 110 and the PCBA plate 220, rather than on the outward-facing side of the plate 220. In this design, the PCBA plate 220 is fixed with respect to the fixed-side bracket 100 and serves as a stationary reference, while the connector PCBA 110 is mounted to the plate 220 for limited linear translation along the insertion axis against the force of the resilient members 210. Guidance is provided by shoulder-screw-through-slot features, guide posts with low-profile bushings, or rail-and-channel profiles formed on the plate 220, and positive stops at the ends of the slots set a defined maximum stroke sized to accommodate accumulated dimensional tolerances without over-travel. The resilient members 210 may be coil springs captured over the guides with the screw heads acting as spring seats and free-length limiters, or compact Belleville/wave springs where height is constrained; in all cases they are preloaded at a home position so initial connector touch occurs under non-zero axial force.

This internal spring arrangement maintains the same functional behavior (as the one shown in FIG. 2A) during use: as the storage device 150 advances, the mating connector 120 and the connector PCBA 110 translate rearward relative to the fixed PCBA plate 220, compressing the resilient members 210; once the device is latched, the springs remain partially compressed to maintain an axial compressive preload across the mated connectors.

FIG. 3 illustrates a side view of the storage-device bay assembly with the movable connector subassembly of FIG. 2. The view shows resilient members 210 disposed on an exterior surface of a PCBA plate 220 of the movable connector subassembly 200, each resilient member 210 being captured beneath an abutment fixed relative to the fixed-side bracket 100 (for example a screw head) so that the abutment reacts the spring force. The arrows (labeled “Direction of spring force”) indicate the bias that urges the movable connector subassembly 200 toward a home position adjacent the fixed-side bracket 100 while permitting controlled rearward translation along the insertion axis when a storage device 150 is pushed in and its device-side connector engages the mating connector 120 (e.g., reaching a seated state). In the seated state, the resilient members 210 remain partially compressed and maintain an axial compressive preload across the mated connectors.

In some embodiments, the fixed-side bracket 100 can be seen providing both mechanical support during insertion and retention after seating. During insertion, the fixed-side bracket 100 supports the storage device 150 on guide rails and datum surfaces (not shown) so that the drive advances along the insertion axis without droop or yaw. At the front (a first end opposite the connector end), a locking mechanism can be located to secure the storage device 150 in the seated state (examples include a latch, lever, or captive-screw mechanism integrated with the bay door or carrier), while the opposite, connector end (the second end) carries the movable connector subassembly 200. The fixed-side bracket 100 may further include at least one alignment feature that guides the storage device 150 into coaxial alignment with the mating connector 120 before mating; suitable implementations are tapered lead-ins, chamfered rails, or dowel-and-slot features that center the device-side connector relative to the mating connector 120 as the device approaches first contact.

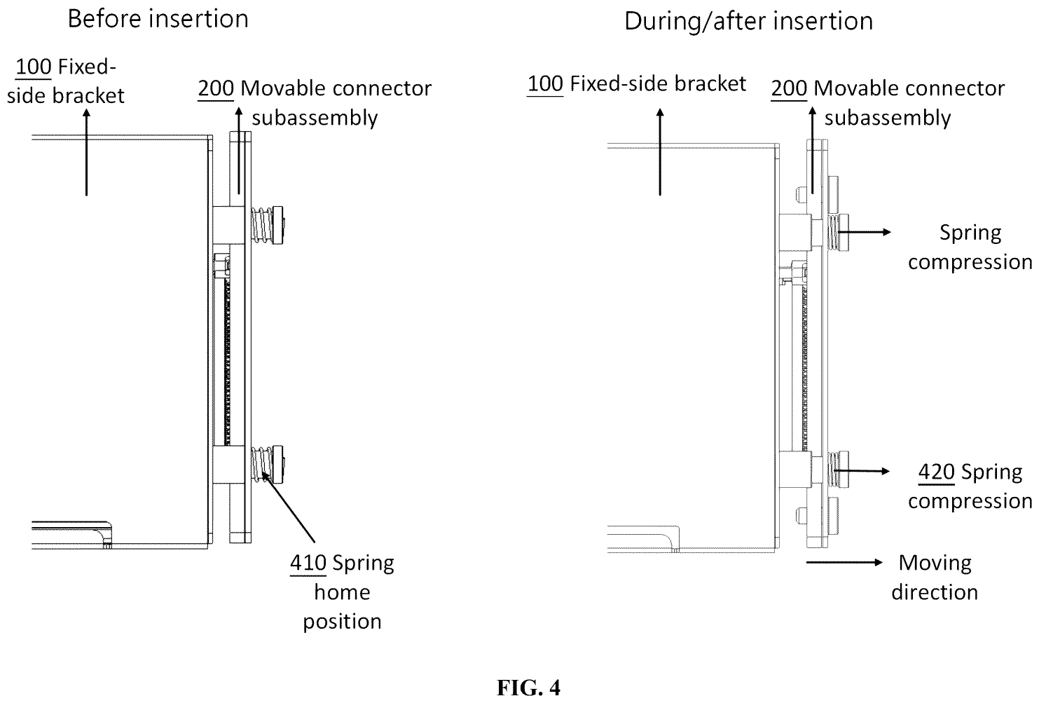

FIG. 4 illustrates a comparison between a pre-insertion state (left) and a during/after-insertion state (right) when a storage device 150 is advanced along the insertion axis toward the storage-device bay. In the pre-insertion state, the storage device 150 is supported by rails or datum surfaces of the fixed-side bracket 100 and guided toward the mating connector 120 carried on the connector PCBA 110. The movable connector subassembly 200, which includes the connector PCBA 110 and the PCBA plate 220, is at a home position adjacent the bracket 100. The resilient members 210, disposed on the exterior face of the subassembly 200 and captured beneath abutments fixed to the bracket 100, bias the movable connector subassembly 200 toward the home position as indicated by the arrows showing the direction of spring force. At this stage the device-side connector of the storage device 150 is not yet in contact with the mating connector 120, but the subassembly 200 is ready to yield rearward along the insertion axis once contact occurs.

In the during/after-insertion state, the storage device 150 has been advanced so that its device-side connector engages the mating connector 120. Continued insertion force translates the entire movable connector subassembly 200 rearward against the resilient members 210, compressing them and absorbing accumulated dimensional tolerances that would otherwise manifest as a fixed gap. The guide features between the subassembly 200 and the fixed-side bracket 100 constrain this motion to linear translation, and a travel stop may bound the maximum rearward stroke. When the storage device 150 reaches its seated position and is latched by the fixed-side bracket 100 (e.g., using a clip at the entrance), the resilient members 210 remain partially compressed so that a non-zero axial compressive preload is maintained across the mated connectors. This preload reduces residual clearance at the interface, raises contact normal force, and stabilizes electrical continuity under vibration and thermal cycling, thereby eliminating the variability inherent in fixed-gap, non-movable connector designs.

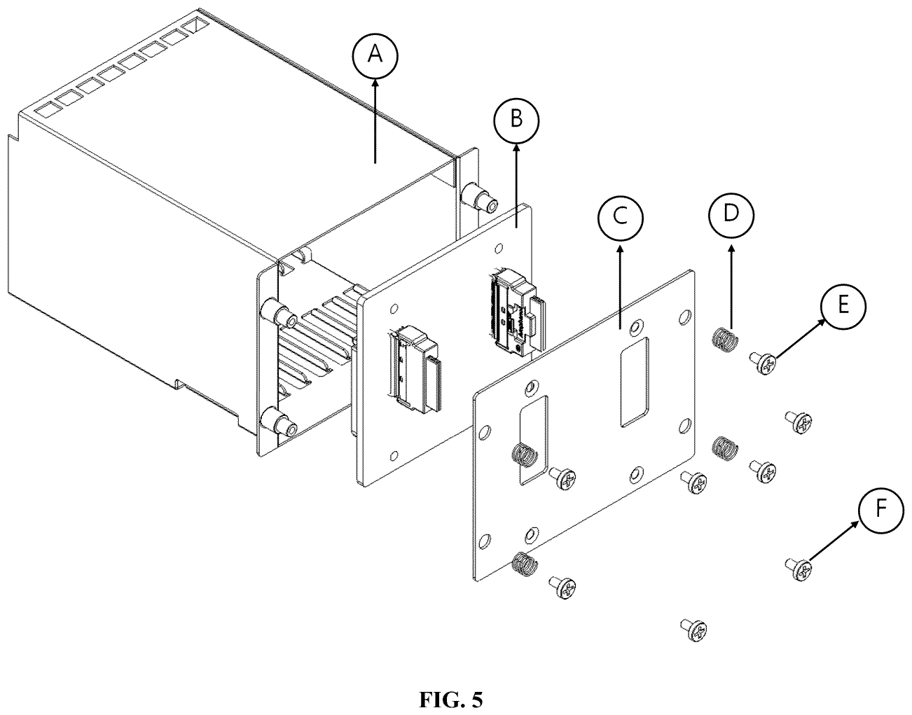

FIG. 5 illustrates a multi-bay storage-device bay assembly in which a single connector PCBA 110 carries a plurality of mating electrical connectors 120 respectively positioned to align with corresponding bay slots of a fixed-side bracket 100. In this design, a movable connector subassembly translates as a single unit along the insertion axis so that all mating electrical connectors 120 move together under the bias of resilient members 210. In the annotated view, A identifies the fixed-side bracket 100 (metal or plastic) that defines the receiving slots and structural datums; B identifies the connector PCBA 110 on the movable side that carries the mating electrical connectors 120; C identifies a PCBA plate 220 on the movable side (metal or plastic) that mechanically supports the connector PCBA 110; D identifies the springs 210 (e.g., metallic coil springs) that provide the bias toward the fixed-side bracket 100; E identifies screws that act as abutments restraining the springs and reacting the spring force; and F identifies fasteners that secure the connector PCBA 110 to the PCBA plate 220. This “translate-together” configuration works well when the storage devices installed in the same enclosure are sourced from the same manufacturer and/or lot, so their dimensional variations are similar; a shared translation then accommodates the common tolerance profile with fewer parts and simpler assembly.

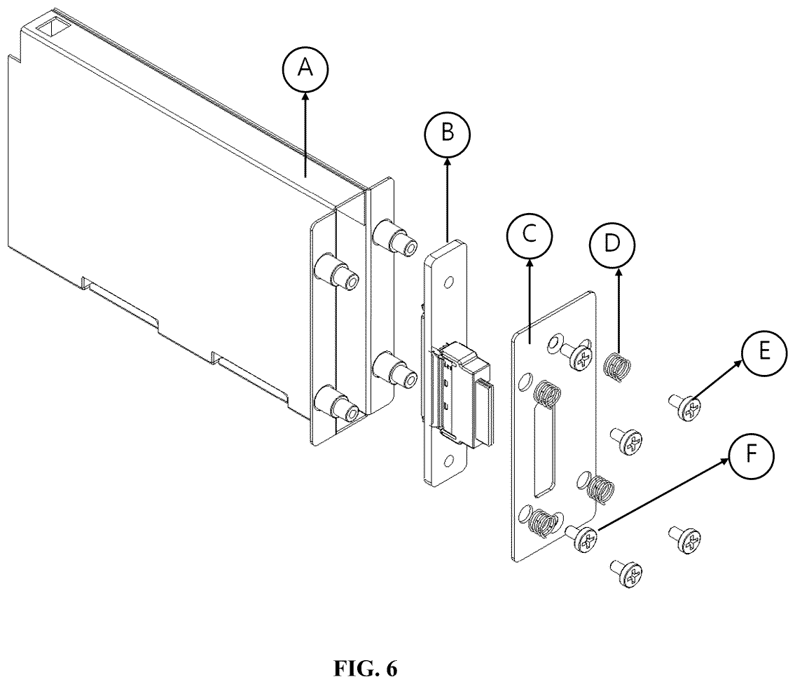

FIG. 6 illustrates an alternative multi-bay configuration in which the movable connector subassembly is subdivided into a plurality of separately movable sections, each section corresponding to a respective bay position. Each section carries its own portion of the connector PCBA 110 with a respective mating electrical connector 120, is supported by its own PCBA plate 220, and is biased by its own resilient member 210 that is captured under an abutment screw E; fasteners F secure the section's connector PCBA 110 to its PCBA plate 220. During insertion, the section aligned to the incoming storage device translates independently along the insertion axis while neighboring sections remain substantially stationary. In the seated state, each section's spring maintains localized axial compressive preload tailored to that particular drive. This “independent-section” approach maximizes resilience to bay-to-bay and device-to-device variation (useful when the enclosure mixes drives from different vendors, different batches, or different carriers) at the tradeoff of higher manufacturing cost and greater mechanical complexity due to the additional moving sections, springs, abutments, and guides.

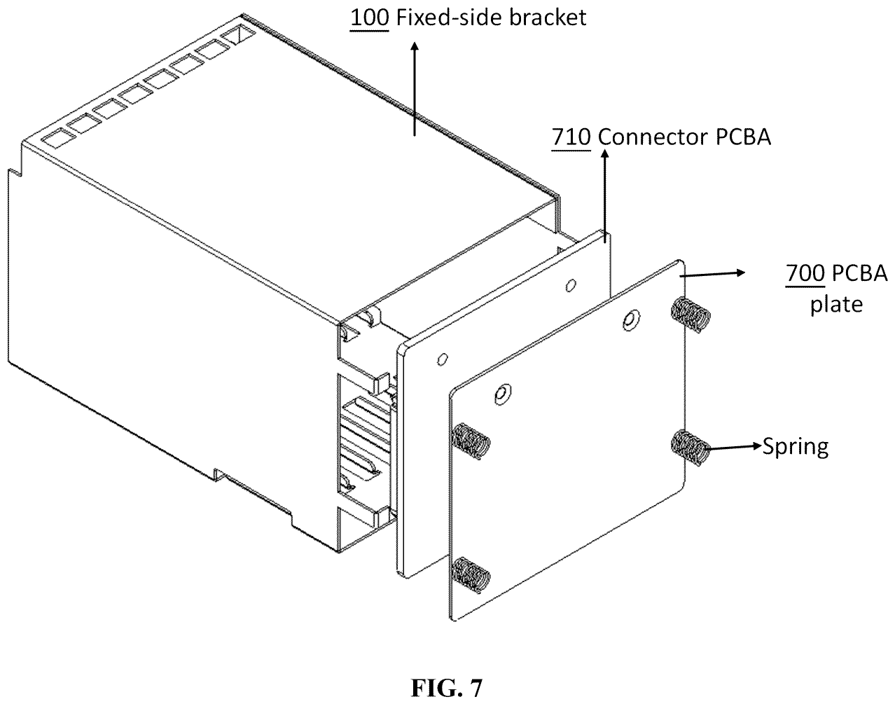

FIG. 7 illustrates an exploded view of a movable connector subassembly arranged for use with a fixed-side bracket 100. In the illustrated build, a connector PCBA 710 is positioned adjacent to the bracket 100 so that its mating connector(s) project toward the incoming storage device, and a PCBA plate 700 is located outboard of the connector PCBA 710 to form a rigid carriage. Resilient members, shown as coil springs, are disposed on the exterior face of the PCBA plate 700 that faces away from the bracket 100. Abutments in the form of screw heads thread into the bracket 100 and overlie the springs 210 to capture them against the plate 220, react the spring force, and act as free-length limiters. When assembled, the connector PCBA 710 and the PCBA plate 700 translate together as a unit relative to the bracket 100, with guide hardware (e.g., shoulder screws in elongated slots, posts and bushings, or rail-and-channel profiles) constraining motion to the insertion axis and an internal stop defining a maximum stroke. This arrangement allows the springs to be installed and serviced from the outboard side while the connector PCBA 710 is “sandwiched” between the bracket 100 and the PCBA plate 700, providing a compact, stiff, and easily replaceable carriage that maintains axial compressive preload across the mated connectors in the seated state.

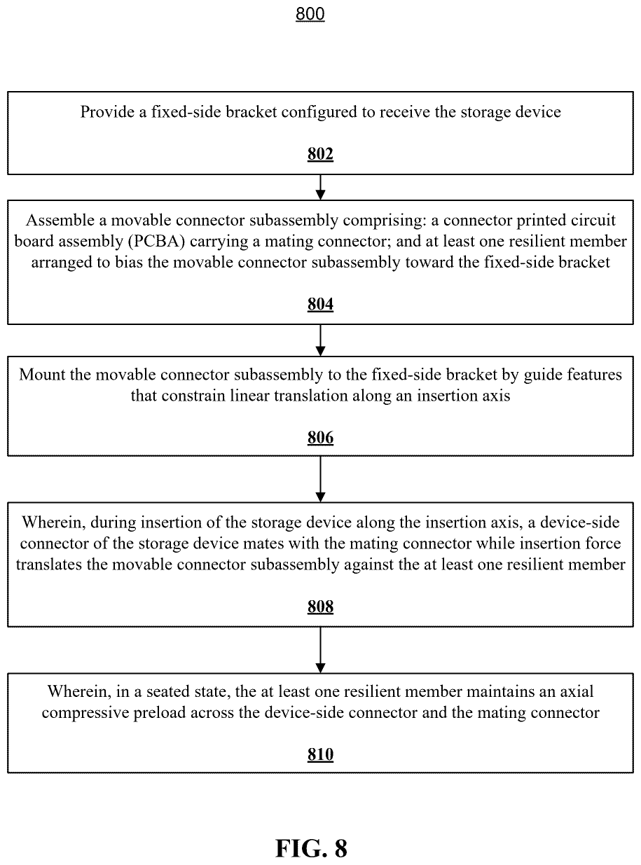

FIG. 8 illustrates an example method 800 of manufacturing a storage-device bay assembly with a movable connector subassembly. At step 802, a fixed-side bracket configured to receive the storage device is provided to establish the chassis interface, bay geometry, and guide datums. At step 804, a movable connector subassembly is assembled. In the illustrated flow, the subassembly includes a connector printed circuit board assembly (PCBA) carrying at least one mating connector and at least one resilient member arranged to bias the movable connector subassembly toward the fixed-side bracket. At step 806, the movable connector subassembly is mounted to the fixed-side bracket by guide features that constrain linear translation along an insertion axis so the connector carriage can move in pure axial motion during mating. Step 808 depicts the intended functional behavior of the manufactured assembly: as a storage device is advanced along the insertion axis, its device-side connector mates with the mating connector while insertion force translates the movable connector subassembly against the resilient member. Step 810 shows that, once the storage device is fully seated, the resilient member remains partially compressed and thereby maintains an axial compressive preload across the mated connectors.

In some embodiments, the resilient member is disposed on an exterior surface of the movable connector subassembly that faces away from the fixed-side bracket and is captured beneath an abutment fixed to the bracket, such as the head of a screw, so that the abutment reacts spring force and establishes a repeatable home position after assembly. In some embodiments, the axial compressive preload present in the seated state is selected to accommodate accumulated dimensional tolerances across the device, carrier, and bay hardware, to reduce residual clearance at the mated interface, and to increase contact normal force so electrical continuity is robust under vibration and thermal cycling. In some embodiments, the movable connector subassembly further includes a PCBA plate that supports the connector PCBA, with the connector PCBA positioned between the PCBA plate and the fixed-side bracket so the plate and the connector PCBA translate together as a rigid carriage relative to the bracket. In some embodiments, the connector PCBA carries a plurality of mating connectors aligned with a corresponding plurality of slots in the fixed-side bracket and the resilient member biases the movable connector subassembly so the plurality of mating connectors translate together along the insertion axis; this variant is advantageous where the installed storage devices are from the same manufacturer or lot and exhibit similar dimensional variation. In other embodiments suited to mixed-vendor or mixed-lot installations, the movable connector subassembly is subdivided into a plurality of separately movable sections, each section carrying a respective mating connector and having a corresponding resilient member that biases that section toward the bracket, so the sections translate substantially independently to provide localized axial compressive preload at each bay position.

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Each process, method, and algorithm described in the preceding sections may be embodied in, and fully or partially automated by, code modules executed by one or more computer systems or computer processors comprising computer hardware. The processes and algorithms may be implemented partially or wholly in application-specific circuitry.

When the functions disclosed herein are implemented in the form of software functional units and sold or used as independent products, they can be stored in a processor executable non-volatile computer readable storage medium. Particular technical solutions disclosed herein (in whole or in part) or aspects that contribute to current technologies may be embodied in the form of a software product. The software product may be stored in a storage medium, comprising a number of instructions to cause a computing device (which may be a personal computer, a server, a network device, and the like) to execute all or some steps of the methods of the embodiments of the present application. The storage medium may comprise a flash drive, a portable hard drive, ROM, RAM, a magnetic disk, an optical disc, another medium operable to store program code, or any combination thereof.

Particular embodiments further provide a system comprising a processor and a non-transitory computer-readable storage medium storing instructions executable by the processor to cause the system to perform operations corresponding to steps in any method of the embodiments disclosed above. Particular embodiments further provide a non-transitory computer-readable storage medium configured with instructions executable by one or more processors to cause the one or more processors to perform operations corresponding to steps in any method of the embodiments disclosed above.

Embodiments disclosed herein may be implemented through a cloud platform, a server or a server group (hereinafter collectively the “service system”) that interacts with a client. The client may be a terminal device, or a client registered by a user at a platform, wherein the terminal device may be a mobile terminal, a personal computer (PC), and any device that may be installed with a platform application program.

The various features and processes described above may be used independently of one another or may be combined in various ways. All possible combinations and sub-combinations are intended to fall within the scope of this disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

The various operations of exemplary methods described herein may be performed, at least partially, by an algorithm. The algorithm may be comprised in program codes or instructions stored in a memory (e.g., a non-transitory computer-readable storage medium described above). Such an algorithm may comprise a machine learning algorithm. In some embodiments, a machine learning algorithm may not explicitly program computers to perform a function but can learn from training data to make a prediction model that performs the function.

The various operations of exemplary methods described herein may be performed, at least partially, by one or more processors that are temporarily configured (e.g., by software) or permanently configured to perform the relevant operations. Whether temporarily or permanently configured, such processors may constitute processor-implemented engines that operate to perform one or more operations or functions described herein.

Similarly, the methods described herein may be at least partially processor-implemented, with a particular processor or processors being an example of hardware. For example, at least some of the operations of a method may be performed by one or more processors or processor-implemented engines. Moreover, the one or more processors may also operate to support performance of the relevant operations in a “cloud computing” environment or as a “software as a service” (SaaS). For example, at least some of the operations may be performed by a group of computers (as examples of machines including processors), with these operations being accessible via a network (e.g., the Internet) and via one or more appropriate interfaces (e.g., an Application Program Interface (API)).

The performance of certain of the operations may be distributed among the processors, not only residing within a single machine, but deployed across a number of machines. In some example embodiments, the processors or processor-implemented engines may be located in a single geographic location (e.g., within a home environment, an office environment, or a server farm). In other example embodiments, the processors or processor-implemented engines may be distributed across a number of geographic locations.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, C, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. An assembly for coupling a storage device to a host, comprising:
a fixed-side bracket configured to receive the storage device;
a movable connector subassembly mounted to the fixed-side bracket for linear translation along an insertion axis,
the movable connector subassembly comprising:
a connector printed circuit board assembly (PCBA) carrying a mating connector; and
at least one resilient member arranged to bias the movable connector subassembly toward the fixed-side bracket;
wherein the mating connector is configured to mate with a device-side connector of the storage device while an insertion force applied to the storage device translates the movable connector subassembly against the at least one resilient member; and
wherein the at least one resilient member is configured to maintain an axial compressive preload across the device-side connector and the mating connector when the storage device is in a seated state.

2. The assembly of claim 1, wherein the at least one resilient member is disposed on an exterior surface of the movable connector subassembly that faces away from the fixed-side bracket and is captured between the exterior surface and an abutment fixed to the fixed-side bracket so as to bias the movable connector subassembly toward the fixed-side bracket.

3. The assembly of claim 2, wherein the abutment comprises a screw secured to the fixed-side bracket, the screw having a head that restrains the resilient member.

4. The assembly of claim 3, wherein the at least one resilient member comprises:
a coil spring seated between the exterior surface and the head of the screw, with the head of the screw acting as a spring seat.

5. The assembly of claim 1, wherein the axial compressive preload is configured to:
accommodate accumulated dimensional tolerances,
reduce residual clearance, and
increase engagement force between the storage device and the connector PCBA.

6. The assembly of claim 1, wherein the fixed-side bracket is configured to:
support the storage device during insertion along the insertion axis, and
secure the storage device in a seated state by a locking mechanism located at a first end opposite a second end at which the movable connector subassembly is mounted.

7. The assembly of claim 1, the fixed-side bracket further comprising:
an alignment feature configured to guide the storage device into coaxial alignment with the mating connector prior to mating.

8. The assembly of claim 1, further comprising:
a travel stop that limits translation of the movable connector subassembly away from a home position to a defined stroke.

9. The assembly of claim 1, wherein the movable connector subassembly further comprises:
a PCBA plate that supports the connector PCBA, wherein the connector PCBA is sandwiched between the PCBA plate and the fixed-side bracket.

10. The assembly of claim 9, wherein the PCBA plate is formed of metal or plastic and the fixed-side bracket is formed of metal or plastic.

11. The assembly of claim 1, wherein the storage device comprises a hard disk drive or a solid-state drive, and
the mating connector comprises a SATA, SAS, PCIe, or edge-card interface.

12. The assembly of claim 1, wherein the connector PCBA carries a plurality of mating connectors respectively positioned to align with a corresponding plurality of slots of the fixed-side bracket that are configured to receive a plurality of storage devices.

13. The assembly of claim 12, wherein the at least one resilient member biases the movable connector subassembly such that the plurality of mating connectors translate together along the insertion axis.

14. The assembly of claim 12, wherein the movable connector subassembly comprises a plurality of separately movable sections respectively corresponding to the plurality of mating connectors,
each of the plurality of movable sections carrying a respective mating connector and having a corresponding resilient member that biases that movable section toward the fixed-side bracket,
wherein the plurality of movable sections translate substantially independently along the insertion axis to provide localized axial compressive preload for the plurality of storage devices.

15. A method of manufacturing an assembly for coupling a storage device to a host, the method comprising:
providing a fixed-side bracket configured to receive the storage device;
assembling a movable connector subassembly comprising:
a connector printed circuit board assembly (PCBA) carrying a mating connector; and
at least one resilient member arranged to bias the movable connector subassembly toward the fixed-side bracket; and
mounting the movable connector subassembly to the fixed-side bracket by guide features that constrain linear translation along an insertion axis;
wherein, during insertion of the storage device along the insertion axis, a device-side connector of the storage device mates with the mating connector while insertion force translates the movable connector subassembly against the at least one resilient member, and
wherein, in a seated state, the at least one resilient member maintains an axial compressive preload across the device-side connector and the mating connector.

16. The method of claim 15, wherein the at least one resilient member is disposed on an exterior surface of the movable connector subassembly that faces away from the fixed-side bracket and is captured between the exterior surface and an abutment fixed to the fixed-side bracket so as to bias the movable connector subassembly toward the fixed-side bracket.

17. The method of claim 15, wherein the axial compressive preload is configured to:
accommodate accumulated dimensional tolerances,
reduce residual clearance, and
increase engagement force between the storage device and the connector PCBA.

18. The method of claim 15, wherein the movable connector subassembly further comprises:
a PCBA plate that supports the connector PCBA, wherein the connector PCBA is sandwiched between the PCBA plate and the fixed-side bracket.

19. The method of claim 15, wherein the connector PCBA carries a plurality of mating connectors respectively positioned to align with a corresponding plurality of slots of the fixed-side bracket that are configured to receive a plurality of storage devices, and
the at least one resilient member biases the movable connector subassembly such that the plurality of mating connectors translate together along the insertion axis.

20. The method of claim 15, wherein the connector PCBA carries a plurality of mating connectors respectively positioned to align with a corresponding plurality of slots of the fixed-side bracket that are configured to receive a plurality of storage devices, and
the movable connector subassembly comprises a plurality of separately movable sections respectively corresponding to the plurality of mating connectors,
each of the plurality of movable sections carrying a respective mating connector and having a corresponding resilient member that biases that movable section toward the fixed-side bracket,
wherein the plurality of movable sections translate substantially independently along the insertion axis to provide localized axial compressive preload for the plurality of storage devices.
